(19) United States
(12) Patent Application Publication
(10) Pub. No.: US 2007/0184662 A1
(43) Pub. Date: Aug. 9, 2007

(54) Double-side polishing carrier and fabrication method thereof

(75) Inventors: Kenji Yamashita, Kanagawa (JP); Yukio Oono, Kanagawa (JP); Yuuji Sugimoto, Kanagawa (JP)

Correspondence Address: WELSH & KATZ, LTD, 120 S RIVERSIDE PLAZA, 22ND FLOOR, CHICAGO, IL, 60606, US

(73) Assignee: Komatsu Denshi Kinzoku Kabushiki Kaisha, Kanagawa (JP)

(21) Appl. No.: 11/629,950

(22) PCT Filed: Jun. 23, 2005
(86) PCT No.: PCT/JP05/11548

§ 371 Date: Dec. 18, 2006

(30) Foreign Application Priority Data
Jun. 23, 2004 (JP) 2004-185190

(51) Int. Cl. C03C 15/00; H01L 21/306; B44C 1/22; H01L 21/302

(52) U.S. Cl. 438/692; 156/345.12; 216/88

(57) ABSTRACT

The carrier (10) for double-side polishing has a base material 10a the material of which is stainless steel (SUS) , for example, as is before, and the base material 10a is coated with a coating layer 10b of a material having a hardness higher than that of the base material 10a. The coating layer 10b is desirably coated uniformly without variations in thickness and not warped easily, and the material for the coating layer 10b of the double-side polishing carrier 10 is desirably any one selected from diamond-like carbon, a nitride film, a sapphire film and a titanium nitride film. For production of the double-side polishing carrier 10, a double-side polishing carrier 10′ having been used for polishing is prepared first. The used carrier 10′ is coated with the coating layer 10b. The invention can suppress the progress of abrasion of the double-side polishing carrier, and can provide satisfactory thickness accuracy, film thickness distribution accuracy, and surface roughness.

### TECHNICAL FIELD

The present invention relates to a double-side polishing carrier used for double-side polishing machines and a fabrication method thereof.

### BACKGROUND ART

Silicon wafers are fabricated through individual steps including a lapping step and a polishing step.

In the polishing step, the silicon wafer is simultaneously polished on both sides by means of a double-side polishing machine. In the lapping step, the both sides of the silicon wafer are simultaneously lapped by means of a both-side lapping apparatus. The outline of the apparatus will be described below with reference to the double-side polishing machine as a representative.

FIG. 2 is a side view of a double-side polishing machine 100. FIG. 1 is a top view taken in the direction of arrows A of the double-side polishing machine 100 of FIG. 2, showing a positional relationship among double-side polishing carriers 10, silicon wafers 1 and a lower platen 102.

The double-side polishing machine 100 comprises the double-side polishing carriers 10 which hold peripheral edges 1c of the silicon wafers 1 within holding openings 11 to accommodate the silicon wafers 1 with front sides 1a and back sides 1b exposed, and an upper platen 101 and the lower platen 102 which are respectively mounted on the sides of the front sides 1a and the back sides 1b of the silicon wafers 1 and have polishing cloth 103, 104 bonded to their surfaces.

The silicon wafers 1 are housed within the holding openings 11 of the double-side polishing carriers 10, and the upper platen 101 and the lower platen 102 are moved toward the silicon wafers 1. Thus, the polishing cloth 103, 104 are pushed against the front sides 1a and the back sides 1b of the silicon wafers 1, the double-side polishing carriers 10, the upper platen 101 and the lower platen 102 are relatively rotated in opposite directions while supplying a polishing slurry between the front sides 1a of the silicon wafers 1 and the polishing cloth 103 of the upper platen 101, and between the back sides 1b of the silicon wafer 1 and the polishing cloth 104 of the lower platen 102. As a result, the front sides 1a and the back sides 1b of the silicon wafers 1 are respectively polished for a prescribed polishing volume so as to have a mirror-finished state.

The double-side polishing carriers 10 have, for example, six holding openings 11 and polish six silicon wafers 1 simultaneously.

The polishing cloth 103, 104 are pushed against not only the both sides of the silicon wafers 1 but also the both sides of the double-side polishing carriers 10. Therefore, the abrasion of the double-side polishing carriers 10 progresses with the increase of the polishing time, and the double-side polishing carriers 10 used for polishing for a prescribed time period or prescribed times are replaced with new double-side polishing carriers 10.

Material for the double-side polishing carrier 10 is generally stainless steel.

But, the double-side polishing carriers 10 made of stainless steel have low thickness accuracy and are variable in thickness. Therefore, the individual silicon wafers 1 which are finished by the individual double-side polishing carriers 10 have a disadvantage that their flatness is variable. Besides, there is a problem that the double-side polishing carriers 10 are abraded quickly. Therefore, there is a problem that the silicon wafers 1 are variable in flatness depending on the progress of the abrasion of the double-side polishing carriers 10, so that they cannot be provided with stable flatness.

There is also a problem that where the double-side polishing carriers 10 are worn, metal powder produced as a result causes metal contamination of the silicon wafers 1. And, there is another problem that where the double-side polishing carriers 10 are worn, the metal powder produced as a result causes scratches on the surfaces of the silicon wafers 1. Because the double-side polishing carriers 10 are worn quickly, a replacement cycle of the double-side polishing carriers 10 is short, resulting in high cost.

Besides, the front sides of the double-side polishing carriers 10 have high roughness and a high a friction coefficient, so that the polishing cloth 103, 104 which are pushed against the double-side polishing carriers 10 and rotated are also worn quickly. Therefore, the replacement cycle of the polishing cloth 103, 104 becomes short, resulting in high cost.

Patent Literature 1 describes an invention that the front side of a metal carrier is coated with a resin.

Patent Literature 2 describes an invention that a carrier is configured of a laminated plate having carbon fiber impregnated with a resin.

Patent Literature 3 describes an invention that an outer peripheral gear portion of a carrier to which a mechanical load is applied is configured of a metal material, the front side is coated with a resin, and the remaining inside area is configured of a resin material.

Recently, it is particularly necessary to produce an electron device having line widths equal to or less than 0.13 μm. To obtain a silicon wafer suitable for production of such an electron device, it is demanded to prepare a silicon wafer having flatness, which is referred to as SFQR, equal to or less than the line widths possessed by the electron device.

The final flatness of the silicon wafer is formed by a polishing process. To produce a silicon wafer having highly accurate flatness, a device and method for polishing the front and back sides of the silicon wafer simultaneously are used.

In a case where a silicon wafer having highly accurate flatness is produced by the above so-called double-side polishing, the thickness of the carrier for holding the silicon wafer when polishing is important.

For example, Patent Literature 4 describes that a silicon wafer having highly accurate flatness can be obtained by setting the final thickness of the silicon wafer to be 2 to 20 μm larger than the carrier thickness.

Patent Literatures 5 and 6 describe that a silicon wafer having highly accurate flatness can be obtained by setting the peripheral part of a carrier for holding the silicon wafer to have thickness equal to or slightly larger than the final thickness of the silicon wafer.

Thus, a range of carrier thickness required is variable depending on the polishing conditions, but it is required to set the carrier thickness or its thickness in part to a particular size with high accuracy in order to obtain a silicon wafer having highly accurate flatness. As described above, it is necessary to improve the accuracy of the carrier thickness in order to obtain particular thickness with high accuracy so as to realize a silicon wafer having highly accurate flatness.

The polishing applies a heavy load to inner walls 1a of holding openings 11 formed in a base material 10a of the double-side polishing carriers 10 and edge surfaces 1c of the silicon wafers 1. Therefore, the edge surfaces 1c of the silicon wafers 1 might be damaged. In order to prevent the silicon wafers 1 from being damaged, a resin insert for absorbing a load may be fitted in the holding openings 11.

FIG. 7 is a plan view showing a conventional state that a resin is fitted into a holding opening.

In order to prevent a resin insert 15 from dislocating or corotating, wedges 10b are formed on the inner wall 1a of the base material 11a, and wedges 15b are also formed on an outer side wall 15a of the resin insert 15. Wedges 10c and the wedges 15b are mutually engaged to fix the resin insert 15 to the base material 10a.

[Patent Literature 1]

Japanese Utility Model Application Laid-Open Publication No. Sho 58-4349
   [Patent Literature 2]
Japanese Patent Application Laid-Open Publication No. Sho 58-143954
   [Patent Literature 3]
Japanese Patent Application Laid-Open Publication No. Hei 10-329013
   [Patent Literature 4]
Japanese Patent No. 3400765
   [Patent Literature 5]
Japanese Patent Application Laid-Open Publication No. Hei 11-254305
[Patent Literature 6]
Japanese Patent Application Laid-Open Publication No. 2003-19660

### SUMMARY OF THE INVENTION

### Problems to be Solved by the Invention

According to the prior arts described in the Patent Literatures 1 through 3, the carrier has the front side entirely or partly formed of a resin, so that production of metal powder associated with the abrasion of the double-side polishing carrier can be suppressed. Thus, the occurrence of metal contamination or scratches resulting from the production of the metal powder can be prevented.

But, in a case where the carrier surface is simply configured of a resin, an abrasion speed is equal to or higher than that of a metal carrier, and a conventional problem that the replacement cycle of the carrier is short could not be remedied. And, where the carrier surface is simply coated with the resin, sufficient thickness accuracy, film thickness distribution accuracy and surface roughness cannot be obtained, the flatness of the silicon wafer cannot be obtained stably, and the replacement cycle of the polishing cloth cannot be prevented from becoming short.

The present invention has been made in view of the above circumstances and provides a double-side polishing carrier of which abrasion can be suppressed from progressing, and satisfactory thickness accuracy, film thickness distribution accuracy and surface roughness.

### MEANS FOR SOLVING THE PROBLEMS

A first aspect is a double-side polishing carrier which is used for a double-side polishing machine for simultaneously polishing both sides of a subject to be polished and which holds the subject to be polished, wherein:

the carrier is coated with a material having hardness higher than that of a base material for the double-side polishing carrier.

A second aspect relates to the first aspect, wherein the material for coating the double-side polishing carrier is any of diamond-like carbon, a nitride film, a sapphire film and a titanium nitride film.

A third aspect relates to the first aspect or the second aspect, wherein the double-side polishing carrier has a coated thickness of 20 μm or less.

A fourth aspect relates to the first aspect, the second aspect or the third aspect, wherein the coated surface of the double-side polishing carrier has roughness of 0.3 μm or less.

A fifth aspect relates to the first aspect, the second aspect, the third aspect or the fourth aspect, wherein a double-side polishing carrier having been used for polishing is covered with a coating.

A sixth aspect relates to a method for producing a double-side polishing carrier which is used for a double-side polishing machine for simultaneously polishing both sides of a subject to be polished and which holds the subject to be polished, the method comprising:

when applying a coating to the double-side polishing carrier, coating a double-side polishing carrier having been used for polishing with a material having a hardness higher than that of the base material.

The double-side polishing carrier 10 of the first aspect has stainless steel (SUS) for the base material 10a in the same manner as prior art as shown in FIG. 4, and the base material 10a is coated with a coating layer 10b of material having hardness higher than that of the base material 10a.

The coating layer 10b is desirably formed uniformly without variations in thickness and not warped easily. The material for the coating layer 10b of the double-side polishing carrier 10 is desirably any of diamond-like carbon, a nitride film, a sapphire film and a titanium nitride film. Among them, the diamond-like carbon is particularly desirable because it is lightweight (the second aspect).

The coating layer 10b of the double-side polishing carrier 10 desirably has a thickness of 20 μm or less (the third aspect).

The surface roughness of the double-side polishing carrier 10, namely the surface roughness of the coating layer 10b, is desirably, for example, 0.3 μm or less for Ra (the fourth aspect).

Where the silicon wafers 1 are polished by the above-described double-side polishing carriers 10, the double-side polishing carriers 10 have high thickness accuracy and variations in thickness of the individual carriers become small, variations in flatness of the individual silicon wafers 1 finished by the individual double-side polishing carriers 10 are reduced, and stable flatness can be obtained. Besides, the progress of the abrasion of the double-side polishing carriers 10 becomes slow, variations in flatness of the individual silicon wafers 1 obtained depending on a lapse of time is decreased, and stable flatness can be obtained.

And, the production of metal powder of copper, iron, chrome or the like associated with the abrasion of the double-side polishing carriers 10 is substantially eliminated, and metal contamination because of the intrusion of copper into the bulk of the silicon wafers 1 is substantially prevented from occurring. And, the production of metal powder associated with the abrasion of the double-side polishing carriers 10 is substantially eliminated, and the surfaces of the silicon wafer 1 become substantially free from a scratch.

The progress of the abrasion of the double-side polishing carriers 10 becomes slow, the replacement cycle of the double-side polishing carriers 10 becomes long, and the cost is reduced.

Besides, the surface roughness of the double-side polishing carriers 10 is low and a friction coefficient becomes low, so that the abrasion of the polishing cloth 103, 104 which are pushed against the double-side polishing carriers 10 and rotated becomes slow. Therefore, the replacement cycle of the polishing cloth 103, 104 becomes long, and the cost is reduced.

To conduct the method for producing the double-side polishing carrier 10 of the sixth aspect, a double-side polishing carrier 10′ which was used for polishing is prepared. The used double-side polishing carrier 10′ may be a carrier which does not have the coating layer 10b formed of stainless steel in the same manner as the prior art or may be a carrier on which the above-described coating layer 10b is formed.

Then, the used carrier 10′ is coated with the coating layer 10b.

When the double-side polishing carrier 10 is produced by the above production method, the production cost per silicon wafer can be reduced considerably because the used carrier is reused.

A seventh aspect relates to a double-side polishing carrier which is used for a double-side polishing machine for simultaneously polishing both sides of a subject to be polished, has a resin disposed on inner walls of holding openings formed in a base material, and holds the subject to be polished by the resin, wherein:

a bonded portion between the base material and the resin is coated with a material having a hardness higher than that of the base material.

As shown in FIG. 7, to fix the resin insert 15 to the base material 10a of the double-side polishing carrier 10, it is generally necessary to dispose a peculiar shape such as the wedges 10c or the wedges 15b on the inner wall 11a of the holding openings 11 or the outer side wall 15a of the resin insert 15 formed in the base material 10a. To form such a shape, it is necessary to increase the fabrication works of the base material 10a and the resin insert 15, but there are problems that manufacturing efficiency of the base material 10a and the resin insert 15 lowers, and the production cost increases.

As shown in FIG. 8, the seventh aspect has the base material 10a and a resin 20 coated with a coating layer 21 of a material having hardness higher than that of the base material 10a. In other words, the coating layer 21 covers a bonded portion 22 between the base material 10a and the resin insert 20. The resin insert 20 is fixed to the base material 10a with the coating layer 21. Therefore, the same effect as that provided by the first aspect can be obtained according to the seventh aspect, and the fabrication of the base material and the resin insert is facilitated because the base material and the resin insert do not require the wedges. Thus, the manufacturing efficiency of the base material and the resin insert is improved, and the production cost is reduced. And, damage to the silicon wafer is decreased because the silicon wafer is held by the resin insert.

### BEST MODE FOR CARRYING OUT THE INVENTION

A double-side polishing carrier according to the present invention will be described with reference to the drawings. It is assumed in the embodiments that silicon wafers are polished by means of a double-side polishing carrier. It should be understood that “polishing” used through the specification includes a meaning of lapping, and the “double-side polishing carrier” is used as a double-side polishing carrier to be used for a double-side polishing machine in the polishing step, and also means a carrier used for a double-side polishing machine (both-side lapping apparatus) in the lapping step.

The double-side polishing carrier of the invention can also be used to polish not only the silicon wafers but also other semiconductor wafers of gallium arsenide and the like.

FIG. 2 is a side view of the double-side polishing machine 100. FIG. 1 is a top view taken in the direction of arrows A of the double-side polishing machine 100 of FIG. 2, showing a positional relationship among the double-side polishing carriers 10, the silicon wafers 1 and the lower platen 102.

The double-side polishing machine 100 generally comprises the double-side polishing carriers 10 which hold the peripheral edges 1c of the silicon wafers 1 within the holding openings 11 to accommodate the silicon wafers 1 with the front sides 1a and the back sides 1b exposed, and the upper platen 101 and the lower platen 102 which are respectively disposed on the sides of the front sides 1a and the back sides 1b of the silicon wafers 1 and have the polishing cloth 103, 104 bonded to their front sides.

A cooling water passage 106 is formed in the upper platen 101, and a cooling water passage 108 is also formed in the lower platen 102. Passages for polishing slurry 107 which are communicated with the surface of the polishing cloth 103 are formed in the upper platen 101, and passages for polishing slurry (not shown) which are communicated with the surface of the polishing cloth 104 are also formed in the lower platen 102.

FIG. 3 shows a magnified form of the double-side polishing carrier 10 of FIG. 1.

Referring to FIG. 3 in addition to FIG. 1 and FIG. 2, the double-side polishing carrier 10 is formed to have a disk-like shape and has, for example, six holding openings 11 formed to accommodate the silicon wafers 1 at equal intervals in the circumferential direction. Gear teeth 12 (planetary gear) are formed along the outer periphery of the double-side polishing carrier 10, engaged with a sun gear 102a formed at the center of the lower platen 102, and also engaged with an inside gearwheel 105 which is disposed along the outer periphery of the lower platen 102. Five double-side polishing carriers 10 are disposed at equal intervals in the circumferential direction of the lower platen 102 with the sun gear 102a at the center.

In a case where the silicon wafers 1 are polished, the silicon wafers 1 are put in the holding openings 11 of the double-side polishing carriers 10. The upper platen 101 and the lower platen 102 are moved toward the silicon wafers 1, so that the polishing cloth 103, 104 are respectively pushed against the front sides 1a and the back sides 1b of the silicon wafers 1. And, the double-side polishing carriers 10, the upper platen 101 and the lower platen 102 are relatively rotated in opposite directions while supplying the polishing slurry between the front sides 1a of the silicon wafers 1 and the polishing cloth 103 of the upper platen 101 and between the back sides 1b of the silicon wafers 1 and the polishing cloth 104 of the lower platen 102.

The double-side polishing carriers 10 rotate on their axes in the direction indicated by arrow B in FIG. 1 and also rotate in the circumferential direction of the sun gear 102a as indicated by arrow C.

Thus, the front sides 1a and the back sides 1b of the silicon wafers 1 are respectively polished for a prescribed polishing volume to have a mirror polished state. As described above, the double-side polishing carriers 10 each are formed to have, for example, six holding openings 11, so that the single double-side polishing carrier 10 can polish six silicon wafers 1 simultaneously.

FIG. 4 shows a sectional view of the double-side polishing carrier 10.

As shown in FIG. 4, the double-side polishing carrier 10 has stainless steel (SUS) as the material for the base material 10a in the same way as the prior art, and the base material 10a is covered with a coating layer 10b of a material having hardness higher than that of the base material 10a.

The coating layer 10b is desirably coated uniformly without variations in thickness and not warped easily. And, the material for the coating layer 10b of the double-side polishing carrier 10 is desirably any of diamond-like carbon, a nitride film, a sapphire film, and a titanium nitride film. Among them, the diamond-like carbon is especially desirable because it is lightweight and provides good uniform coating.

The material for the base material 10a of the double-side polishing carrier 10 may be metal or resin assumed in this embodiment.

In a case where the base material 10a of the double-side polishing carrier 10 is metal, it may be stainless steel (SUS) as described above or may be steel. Specific material for the base material 10a may be SK material, 18-8 stainless steel, Cr steel, super Cr steel or the like. When the base material 10a of the double-side polishing carrier 10 is metal, it may be entirely formed of metal or partly formed of a resin. For example, in the double-side polishing carrier 10, the inner peripheral surfaces 1 a of the holding openings 11, namely the contact surfaces 11a with the edge surfaces 1c of the silicon wafers 1, may be formed of the resin (see FIG. 3).

When the base material 10a of the double-side polishing carrier 10 is a resin, the coating layer 10b of a different material may be formed on the resin, and the coating layer 10b of the same material as that of the resin of the base material 10a may be formed.

Flatness of the silicon wafer 1 depends on the thickness accuracy of the carrier 10. The thickness accuracy of the carrier 10 depends on the thickness accuracy in the production process of the carrier 10 and the thickness accuracy depending on thermal expansion during the polishing process. As to the thickness accuracy of the carrier 10, the carrier 10 formed of the base material 10a which is a resin is superior to the carrier 10 formed of the base material 10a which is metal. Meanwhile, as to the metal contamination to the silicon wafers 1, the carrier 10 formed of the base material 10a which is a resin is superior.

The coating layer 10b of the double-side polishing carrier 10 is desirably 20 μm or less in thickness. It is because the carrier 10 is warped considerably as the thickness of the coating layer 10b increases.

Surface roughness of the double-side polishing carrier 10, namely the surface roughness of the coating layer 10b , is desirably, for example, 0.3 μm or less for Ra. It is because if the surface roughness of the coating layer 10b is excessively large, the polishing cloth 103, 104 have a shortened life.

In a case where the double-side polishing carrier 10 is coated with the coating layer 10b, at least portions excepting the contact surfaces 11a which are in contact with the edge surfaces 1c of the silicon wafers in the holding openings 11 are coated, and the contact surfaces 11a are desirably coated with a resin which does not apply a load to the edge surfaces 1c of the silicon wafers.

The double-side polishing carrier 10 may be coated entirely, only one side may be coated, or only the portions excepting the gear teeth 12 may be coated.

Where the above-described double-side polishing carriers 10 are used to polish the silicon wafers 1, stable flatness can be obtained because the double-side polishing carriers 10 have highly accurate thickness, variations in thickness of the individual carriers become small, and variations in flatness of the individual silicon wafers 1 finished by the individual double-side polishing carriers 10 become small. Besides, the progress of the abrasion of the double-side polishing carriers 10 become slow, variations in flatness of the individual silicon wafers 1 obtained with a lapse of time become small, and stable flatness can be obtained.

Generation of metal powder such as copper, iron or chrome associated with the abrasion of the double-side polishing carrier 10 is substantially eliminated, and metal contamination due to migration of copper into the bulk of the silicon wafers 1 hardly occurs. And, generation of metal powder associated with the abrasion of the double-side polishing carrier 10 is substantially eliminated, and scratches hardly occur on the surface of the silicon wafer 1.

The progress of the abrasion of the double-side polishing carrier 10 is delayed, the replacement cycle of the double-side polishing carriers 10 is extended, and the cost can be reduced.

Besides, the surface roughness of the double-side polishing carriers 10 is lowered, a friction coefficient is lowered, and the abrasion of the polishing cloth 103, 104 which are pushed against the double-side polishing carriers 10 and rotated is delayed. Therefore, the replacement cycle of the polishing cloth 103, 104 is extended and the cost can be reduced.

Examples (test results) which prove the above-described effects are shown in FIG. 5 and FIG. 6.

FIG. 5B shows variations in flatness SFQR (μm) of the silicon wafers 1 polished by using the double-side polishing carriers 10 of the embodiment described above. The horizontal axis of FIG. 5B represents the flatness SFQR (μm), and the vertical axis represents quantity N of the silicon wafers 1. A comparative example of using conventional double-side polishing carriers 10 not coated with the coating layer 10b is shown in FIG. 5A.

The polishing conditions are as follows.
Material wafer: P type<100> 0.005 to 10Ω
Polishing machine: Double-side polishing machine
Polishing cloth : Nonwoven type, hardness 80 (Asker C hardness)
Polishing slurry: Colloidal silica (pH=11)
Polishing load: 120 g/cm²
Carrier: φ=720 mm, t=700 μm, φ200 mm (dia.) six wafers loaded

Flatness of the silicon wafer 1 was measured by ADE9700.

It is apparent by comparing FIG. 5A and FIG. 5B that the flatness of the wafers obtained by using the conventional double-side polishing carrier 10 is deteriorated because the carriers 10 are abraded with the increase in the number of times of using the carriers, so that variations in flatness of the wafers are large with plural polishing batches (FIG. 5A; Ave. 0.071 μm, Std. 0.05). Meanwhile, it was confirmed that when the double-side polishing carriers 10 of this embodiment were used, the abrasion of the carriers 10 associated with the increase in the number of times of using the carriers could not be confirmed at all, and good flatness of the wafers could be kept even with plural polishing batches (FIG. 5B; Ave. 0.053 μm, Std. 0.02).

FIG. 6 is a graph showing comparison between an abraded amount of the double-side polishing carrier 10 of the embodiment and that of a conventional double-side polishing carrier 10. FIG. 6 indicates the number of polishing batches along the horizontal axis and the accumulated value (μm) of abraded amounts of the carrier along the vertical axis. In FIG. 6, mark ▴ indicates plots of the accumulated value (μm) of abraded amounts of the carrier 10 of stainless steel, which is not coated with the coating layer 10b, of the comparative example, and mark ● indicates plots of the accumulated value of abraded amounts of the carrier 10 of the embodiment having the entire surface of the base material 10a of stainless steel coated with the coating layer 10b of diamond-like carbon.

The polishing conditions are as follows:
Polishing machine: Double-side polishing machine
Polishing cloth: Nonwoven type, hardness 80 (Asker C hardness)
Polishing slurry: Colloidal silica (pH=11)
Polishing load: 120 g/cm²
Polished and removed amount: 15 μm

The wafer 1 to be polished has a size of φ200 mm (dia.).

The thickness of the carrier 10 was measured with a micrometer having a representation unit of 1 μm.

As apparent from FIG. 6, it was confirmed that the conventional double-side polishing carrier 10 used as comparative example was abraded more conspicuously with increasing polishing batches, and where the double-side polishing carrier 10 of this embodiment was used, the abrasion of the carrier associated with the increase of the polishing batches was so small that it could not be confirmed by using a micrometer having a representation unit of about 1 μm.

The wafer having a diameter of 200 mm was used in the examples shown in FIG. 5 and FIG. 6, but the same effects can also be obtained by using wafers having various sizes such as wafers having a diameter of 300 mm.

Then, an example of the method for producing the double-side polishing carrier 10 will be described.

A double-side polishing carrier 10′ having been used for polishing is prepared. The used double-side polishing carrier 10′ may be a carrier formed of the same stainless steel as in the prior art and not having the coating layer 10b or may be a carrier having the above-described coating layer 10b.

Then, the entire surface of the used carrier 10′ is coated with the above-described coating layer 10b excepting the contact surface 11a of the holding opening 11.

The contact surface 11a of the holding opening 11 of the used carrier 10 ′ is coated with a resin.

In a case where the double-side polishing carrier 10 is produced according to the above described production method, the production cost per silicon wafer can be reduced considerably because the used carrier is reused. Besides, the used carrier 10′ has a mirror-finished surface because of its previous use in the polishing step. Thus, it has an advantage that the coating layer 10b can be coated easily.

FIG. 8A to FIG. 8C show sectional views of the double-side polishing carrier of the embodiment that a resin insert is fitted into a holding opening. It is assumed that the holding opening is on the right side in FIG. 8A to FIG. 8C. FIG. 9 is a plan view showing a state of the embodiment that the resin insert is fitted into the holding opening.

Similar to FIG. 4, the double-side polishing carrier 10 has the base material 10a which is formed of stainless steel (SUS) in the same way as the prior art. An annular resin insert 20 is fitted into the holding opening 11 formed in the base material 10a. As shown in FIG. 9, the inner wall 11a of the base material 10a and the outer side wall 20a of the resin insert 20 have a smooth curbed surface, and they are mutually contacted closely. As shown in FIG. 8, the base material 10a and the resin insert 20 which are mutually contacted closely are coated with a coating layer 21 formed of a material having hardness higher than that of the base material 10a.

The bonded portion 22 of the base material 10a and the resin insert 20 is coated with the coating layer 21, so that the base material 10a and the resin insert 20 become one body, and the resin insert 20 is fixed to the base material 10a. The coating layer 21 may have a variety of forms. For example, as shown in FIG. 8A, the coating layer 21 may cover the upper and lower sides of the base material 10a and the upper and lower sides and inner wall of the resin insert 20. As shown in FIG. 8B, the upper and lower sides of the base material 10a and the upper and lower sides of the resin insert 20 may be coated with the coating layer 21. As shown in FIG. 8C, the coating layer 21 may cover the upper and lower sides of the base material 10a and partly cover the upper and lower sides of the resin insert 20.

The coating layer 21 and the base material 10a of FIG. 8 will be described below though the description will partly overlap the description of the above-described coating layer 10b and the base material 10a.

The coating layer 21 is desirably coated uniformly without variations in thickness and not warped easily, and the material for the coating layer 21 of the double-side polishing carrier 10 is desirably any one selected from diamond-like carbon, a nitride film, a sapphire film and a titanium nitride film. Among them, the diamond-like carbon is particularly desirable because it is lightweight and provides a uniform film.

The material for the base material 10a of the double-side polishing carrier 10 is desirably the metal assumed in this example.

In a case where the base material 10a of the double-side polishing carrier 10 is metal, the material may be stainless steel (SUS) as described above or steel. Specific material for the base material 10a may be SK material, 18-8 stainless steel, Cr steel, super Cr steel or the like. Even when the base material 10a of the double-side polishing carrier 10 is metal, the entire body may be metal.

The material for the resin insert 20 may be a nylon resin or the like.

The base material 10a and the resin insert 20 can be prevented from being abraded by coating the coating layer 21 on not only the base material 10a but also the resin insert 20 and the bonded portion between the base material 10a and the resin insert 20. As described above, the resin insert 20 can be fixed to the base material 10a, so that it is not necessary to form wedges or the like on the inner wall 11a of the holding opening 11 formed in the base material 10a and the outer side wall 20a of the resin insert 20. Thus, it becomes easy to fabricate the base material 10a and the resin insert 20. Damage to the silicon wafer 1 can be reduced because the silicon wafer 1 is held by the resin insert 20.

It is desirable that the thickness of the resin insert in the radial direction is thin. The reason will be described with reference to FIG. 10.

FIG. 10A and FIG. 10B are sectional views of the double-side polishing carrier of an embodiment that the resin insert is fitted.

When polishing, the polishing cloth 104 enters a gap 30 formed between a chamfer 1d of the silicon wafer 1 and the resin insert 20. The resin insert 20 is soft and deformed by an effect of the polishing cloth 104 which has entered the gap 30. As shown in FIG. 10A, a deflection amount becomes large when the thickness of the resin insert 20 in the radial direction is large, an amount of the polishing cloth 104 entering the gap 30 increases. Therefore, the periphery of the chamfer 1c of the silicon wafer 1 is polished excessively. Meanwhile, as shown in FIG. 10B, when the thickness of the resin insert 20 in the radial direction is small, the deflection amount becomes small, and the amount of the polishing cloth 104 entering the gap 30 becomes small. Thus, the periphery of the chamfer 1c of the silicon wafer 1 is prevented from being abraded excessively.

In the above-described embodiment, it was described above assuming that polishing was performed by the double-side polishing machine with semiconductor wafers such as silicon wafers housed in the double-side polishing carrier, but the subjects to be polished which are housed in the double-side polishing carrier and polished by the double-side polishing machine are arbitrary.

### BRIEF DESCRIPTION OF THE DRAWINGS

FIG. 1 is a top view of a double-side polishing machine in which double-side polishing carriers are incorporated.

FIG. 2 is a side view of the double-side polishing machine in which the double-side polishing carriers are incorporated.

FIG. 3 is a magnified view of the double-side polishing carrier shown in FIG. 1.

FIG. 4 is a sectional view of the double-side polishing carrier.

FIG. 5A and FIG. 5B are graphs used for description of the effects of the embodiment.

FIG. 6 is a graph used for description of the effects of the embodiment.

FIG. 7 is a plan view showing a conventional state that a resin is fitted into a holding opening.

FIG. 8A to FIG. 8C are sectional views of the double-side polishing carrier of the embodiment that a resin is fitted into a holding opening.

FIG. 9 is a plan view showing a state of an embodiment that a resin is fitted into a holding opening.

FIG. 10A and FIG. 10B are sectional views of the double-side polishing carrier of an embodiment that a resin insert is fitted.

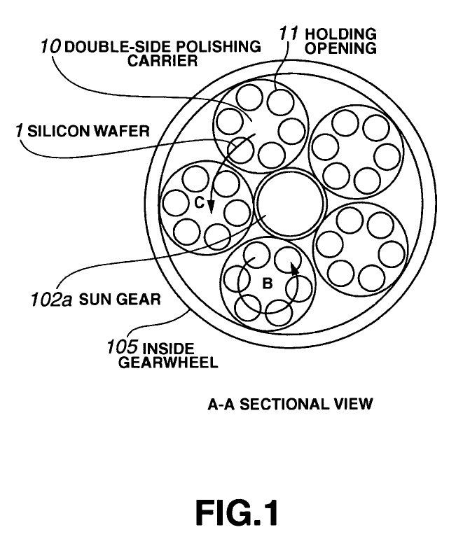

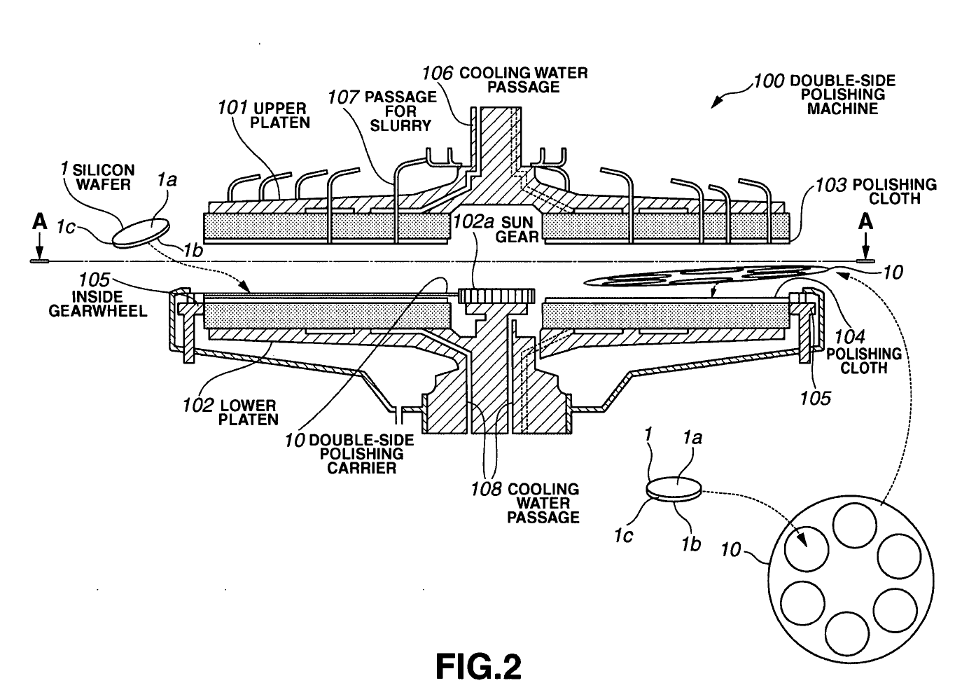

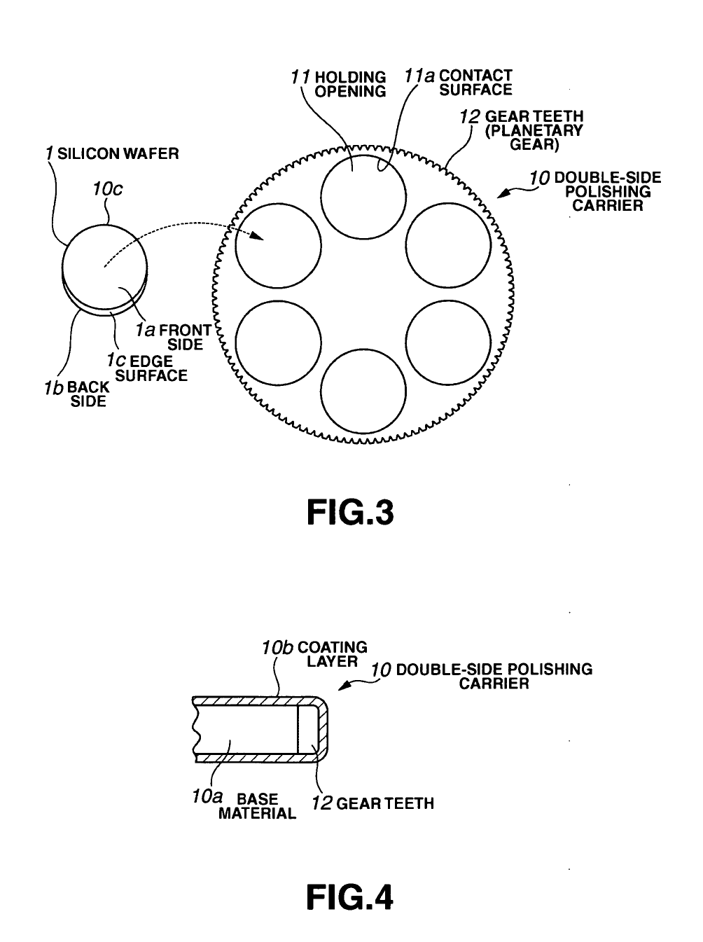

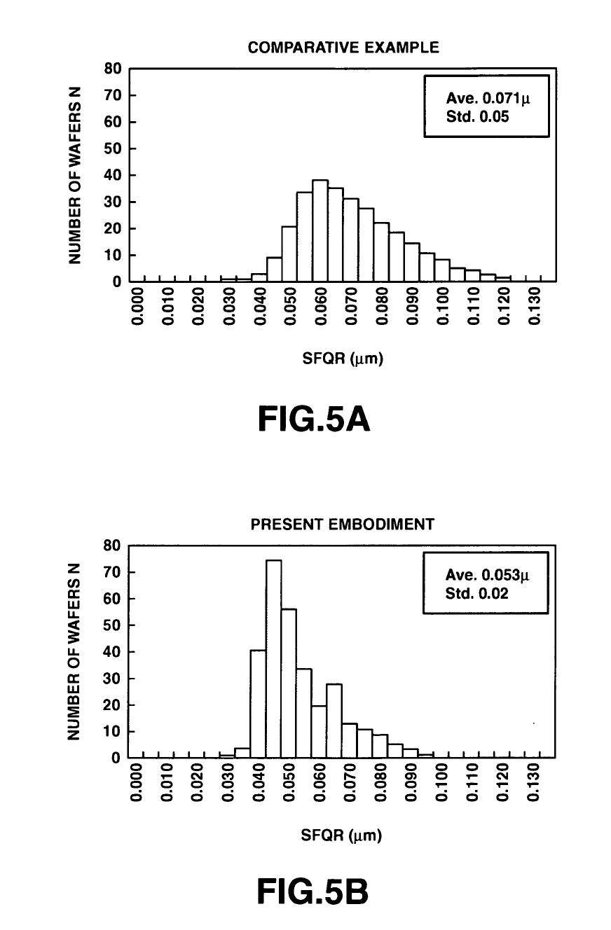

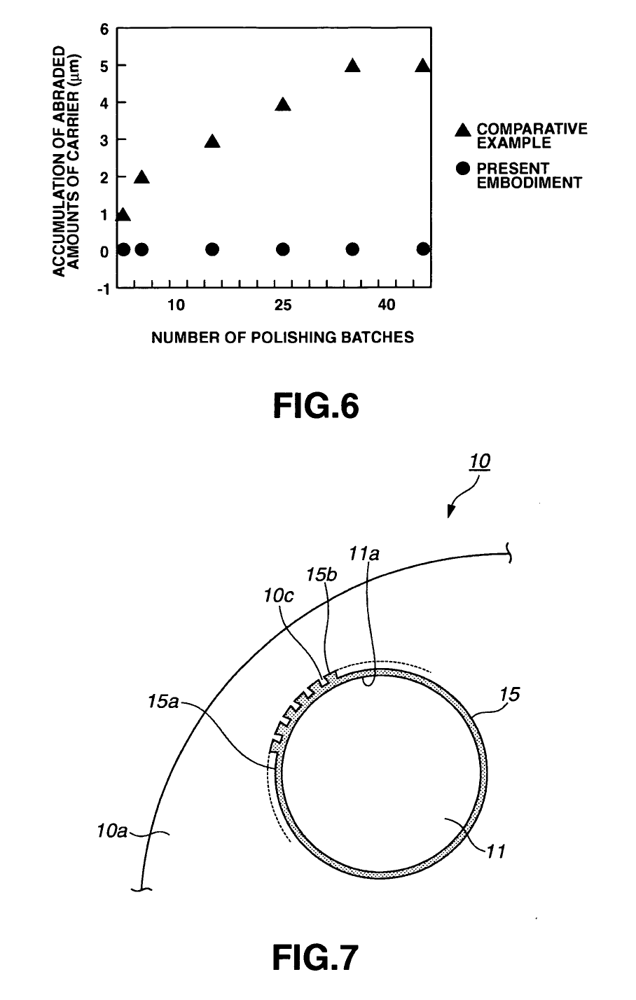

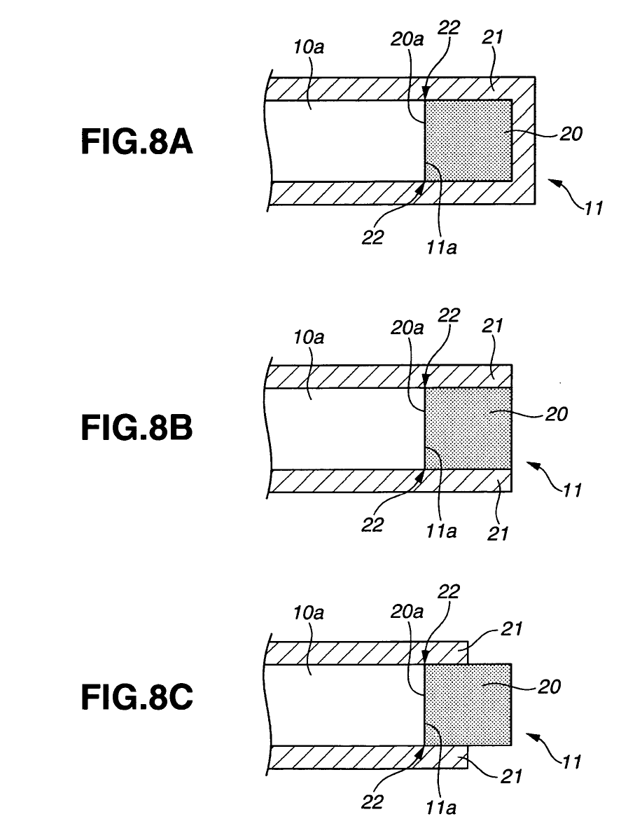

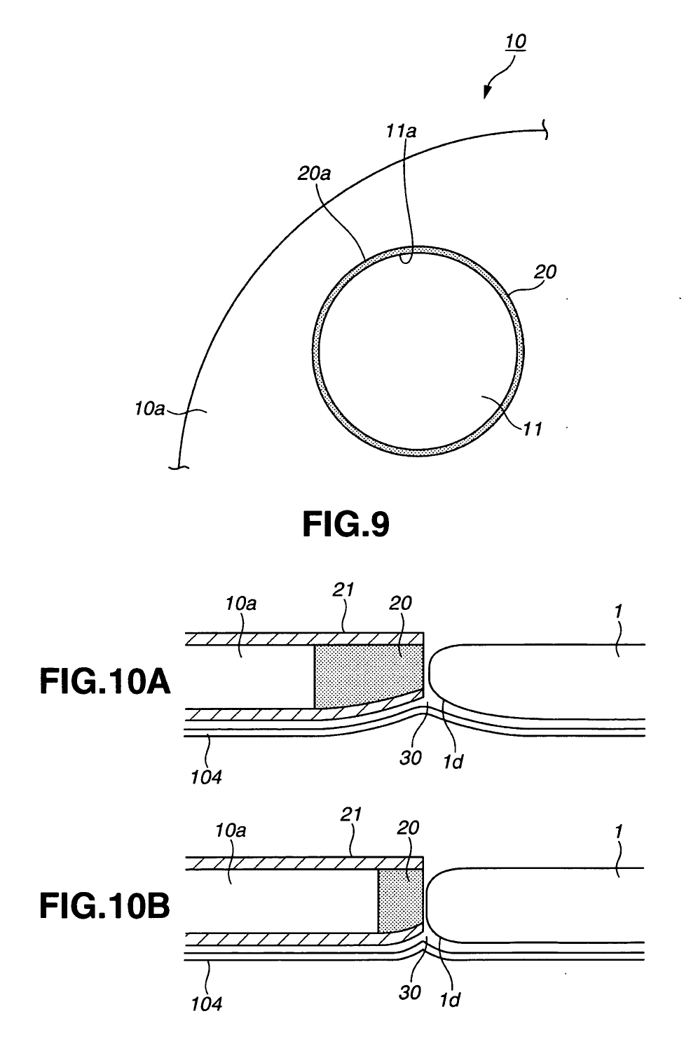

### DESCRIPTION OF THE REFERENCE NUMERALS

1 Silicon wafer
10 Double-side polishing carrier
10a Base material
10b Coating layer
100 Double-side polishing machine

1. A double-side polishing carrier which is used for a double-side polishing machine for simultaneously polishing both sides of a subject to be polished and which holds the subject to be polished, wherein:
the carrier is coated with a material having hardness higher than that of a base material for the double-side polishing carrier.

2. The double-side polishing carrier according to claim 1, wherein the material for coating the double-side polishing carrier is any of diamond-like carbon, a nitride film, a sapphire film and a titanium nitride film.

3. The double-side polishing carrier according to claim 1, wherein the double-side polishing carrier has a coated thickness of 20 μm or less.

4. The double-side polishing carrier according to claim 1, wherein the coated surface of the double-side polishing carrier has a roughness of 0.3 μm or less.

5. The double-side polishing carrier according to claim 1, wherein a double-side polishing carrier having been used for polishing is covered with a coating.

6. A method for producing a double-side polishing carrier which is used for a double-side polishing machine for simultaneously polishing both sides of a subject to be polished and which holds the subject to be polished, the method comprising:
when applying a coating to the double-side polishing carrier, coating a double-side polishing carrier having been used for polishing with a material having a hardness higher than that of the base material.

7. A double-side polishing carrier which is used for a double-side polishing machine for simultaneously polishing both sides of a subject to be polished, has a resin disposed on inner walls of holding openings formed in a base material, and holds the subject to be polished by the resin, wherein:
a bonded portion between the base material and the resin is coated with a material having a hardness higher than that of the base material.
